(19) United States
(12) Patent Application Publication
(10) Pub. No.: US 2003/0062538 A1
(43) Pub. Date: Apr. 3, 2003

(54) Semiconductor device and electronic device using the same

(76) Inventors: Makoto Kudo, Hamura (JP); Kiyoshi Ouchi, Kodaira (JP); Tohru Oka, Osaka (JP); Tomoyoshi Mishima, Shiki (JP)

Correspondence Address: REED SMITH LLP, Suite 1400, 3110 Fairview Park Drive, Falls Church, VA, 22042, US

(21) Appl. No.: 10/144,935

(22) Filed: May 15, 2002

(30) Foreign Application Priority Data
May 16, 2001 (JP) 2001-146357

(51) Int. Cl. H01L 31/0328; H01L 31/0336; H01L 31/072; H01L 31/109

(52) U.S. Cl. 257/197

(57) ABSTRACT

A semiconductor device with improved heat radiation characteristics that is formed by employing a lattice-mismatched system semiconductor thin-film crystal layered product. In fabricating an HBT on a semi-insulating GaAs substrate, the HBT comprised of a material system lattice-matched to InP that is different from the substrate in the lattice constant, a structure is employed that comprises alloy compound semiconductor layers with thermal resistivities that increase with increasing lattice constant (e.g., InₓGa₁₋ₓAs) and alloy compound semiconductor layers with thermal resistivities that decrease with increasing lattice constant (e.g., In_{y}Ga_{1-y}P) as a lattice-strain-relaxed buffer layer. By using the above-mentioned lattice-strain-relaxed buffer layer, the thermal resistivity of the buffer layer can be reduced compared to a lattice-strain-relaxed buffer layer consisting of only InₓGa₁₋ₓAs materials and a lattice-strain-relaxed buffer layer consisting of only In_{y}Ga_{1-y}P materials. Thus, the present invention can provide a compound semiconductor device that is inexpensive and can be mass-produced.

### CLAIM OF PRIORITY

This application claims priority to Japanese Patent Application No. 2001-146357 filed on May 16, 2001.

### BACKGROUND OF THE INVENTION

1. Field of the Invention

The present invention relates to a compound semiconductor device, and, more specifically, the present invention relates to a composition used for a compound semiconductor devices such as a bipolar transistor capable of operating at a high frequency, a high electron mobility transistor, a high-frequency module incorporating the above-mentioned transistors, and electronic devices incorporating the above-mentioned semiconductor devices, such as portable phones and a millimeter wave radar.

2. Description of the Background

Semiconductor devices that are capable of operating at a high frequency are conventionally known to use compound semiconductor materials. Recent examples of such devices include a hetero-junction bipolar transistor having a lattice constant close to that of InP that is manufactured on a GaAs substrate with a lattice-strain-relaxed buffer layer interposed therebetween (hereinafter referred to as “HBT” (Hetero-junction Bipolar Transistor)) as described in IEEE: Electron Device Letters, Vol. 21 (2000), pp. 427-429. Additionally, an exemplary construction in which an AlAs layer having high heat conductivity is inserted between an epitaxially grown semiconductor layer and the GaAs substrate that reduces the thermal resistivity of the buffer layer is described in Japanese PC-A H7-161730.

### SUMMARY OF THE INVENTION

In at least one preferred embodiment, the present invention provides a compound semiconductor electronic device that is inexpensive and can be mass-produced. The present invention also preferably provides a compound semiconductor device including stable characteristics of its semiconductor element that is inexpensive and can be mass-produced, when compared to conventional devices.

Recently, there has been a growing demand to decrease the size and weight of portable telephones. To address this goal, enhancement of the performance of the HBT, especially through decreasing the operating voltage, is important. For example, to reduce the operating voltage of the HBT of an InP system, a material that has a small band gap and a large mobility, such as InGaAs, and that is lattice-matched to InP which is used for the crystal formation substrate, is used for a base layer. However, the InP used as the substrate is expensive and also has a diameter which is more difficult to enlarge compared to a GaAs substrate. Therefore, InP is not suitable for semiconductor devices for portable phones that need to be mass-produced and inexpensive. Because of this fact, as shown in the above-mentioned prior art, it may be necessary to achieve cost reduction by fabrication of the HBT with a lattice constant that is close to that of InP on the GaAs substrate, and which is inexpensive and capable of being enlarged in a diameter, with the lattice-strain-relaxed buffer layer interposed therebetween.

However, in an example of a prior art fabrication of the HBT with a lattice constant that is close to that of InP on the GaAs substrate with the lattice-strain-relaxed buffer layer interposed therebetween, there is a high probability that problems such as thermal runaway may occur due to the lack of consideration for heat radiation. The reason for this is as follows. The heat generated in the normal HBT during the operation is radiated from upper wiring through the emitter electrode and also from a lower cooling body (heat sink) through the buffer layer and the substrate. However, the above-mentioned prior art uses an InGaP lattice-strain-relaxed buffer of which the In content is varied gradually from 0.5 to 1.0 (for example, thickness being 1.5 μm) as the lattice-strain-relaxed buffer layer. In this buffer layer, the heat resistivity for the In content falling between 0.5 and 0.85 can be as large as 10K·cm/W or more compared to 2.27 K·cm/W of the GaAs substrate. This makes it difficult to realize the heat radiation from the lower part of the HBT. Therefore, the heat radiation through the buffer layer becomes insufficient. Because the heat resistivity of InGaP with an In content of 0.5 reaches as high as about 20K·cm/W, it cannot be applied to a semiconductor device that is required to have high heat radiation characteristics.

The relationship between the lattice constant and thermal resistivity for InGaAs and for InGaP in the lattice constant region ranging from GaAs to InP is shown in FIG. 2. In the figure, the horizontal axis is the lattice constant, and the vertical axis is the thermal resistivity. The solid line represents the variation of the thermal resistivity when the composition is changed from InGaP to InP, and the dotted line represents the variation of the thermal resistivity when the composition is changed from GaAs to InGaAs. The values of the thermal resistivity used here are from Handbook Series on Semiconductor Parameters Vol. 2 (1999), World Scientific Publishing Co.

FIG. 2 shows that, with either InGaP or InGaAs, which are typical materials that can be used to change the lattice constant from that of the GaAs to that of the InP, it becomes necessary to use a composition region whose thermal resistivity is as high as approximately 20K·cm/W. Hence, fabrication of a device with increased heat radiation characteristics is difficult. When checking other reported materials, the thermal resistivity of alloy compound semiconductor, consisting of three elements has, in general, a tendency to reach a maximum when the content for one of the elements is close to 0.5. Exemplary values include: 9.2K·cm/W for AlGaAs (a case where the Al content is 0.5); about 20K·cm/W for GaInSb (a case where the Ga content is 0.5); and approximately 9.5K·cm/W for InAsP (a case where the As content is 0.5). It is also noted that the thermal resistivity of alloy compound semiconductors consisting of at least four elements has a tendency of be larger than that of the alloy compound semiconductor consisting of three elements. Therefore, these four element alloys are not suited for the fabrication of devices with increased heat radiation characteristics.

Alternatively, to reduce the thermal resistivity of the buffer layer, a structure may incorporate AlAs (having high heat conductivity) inserted between the epitaxially grown semiconductor layers and the GaAs substrate. However, in this structure, because only the fabrication of the HBT lattice-matched to GaAs is considered, it cannot be applied in fabricating an HBT with a lattice constant that is close to that of InP on the GaAs substrate. The reason for this limitation is that the lattice constant of AlAs is almost the same as that of GaAs and, hence, if the HBT with a lattice constant that is close to that of InP is directly fabricated thereon, a number of dislocation defects due to lattice mismatch may occur and high quality semiconductor layers cannot be obtained.

In a semiconductor device that is formed by employing a lattice-mismatched system semiconductor thin-film crystal layered product such that the semiconductor thin-film crystals, each of which having a different lattice constant in a direction parallel to the above-mentioned substrate crystal plane from that of the above-mentioned substrate, are deposited on the substrate crystal with a buffer layer interposed therebetween, it may become difficult to deposit semiconductor thin-film crystals, each of which having a different lattice constant in a direction parallel to the above-mentioned substrate crystal plane from that of the above-mentioned substrate, while securing sufficient crystallinity without increasing the thermal resistivity (e.g., not spawning a number of dislocation defects due to the lattice mismatch).

In other words, taking a most general case as an example where the substrate is GaAs and semiconductor thin-film crystals to be grown thereon are InP system compound semiconductors, the difficulty is to realize a lattice-strain-relaxed buffer layer with a lattice constant that can be changed gradually from GaAs to InP without increasing the thermal resistivity. Hereafter, taking this semiconductor material system as an example, the present invention will be described. The present invention may be applied to a semiconductor device that is formed by employing the lattice-mismatched system semiconductor thin-film crystal layered product such that semiconductor thin-film crystals, each of which having a different lattice constant in a direction parallel to the above-mentioned substrate crystal plane from that of the above-mention ed substrate, are deposited on a substrate crystal with a buffer layer interposed therebetween.

### BRIEF DESCRIPTION OF THE DRAWINGS

For the present invention to be clearly understood and readily practiced, the present invention will be described in conjunction with the following figures, wherein like reference characters designate the same or similar elements, which figures are incorporated into and constitute a part of th e specification, wherein:

FIG. 1 shows the relationship between the buffer thickness of the buffer layer and the lattice constant and between the buffer thickness and the thermal resistivity for the HBT of a first exemplary embodiment;

FIG. 2 shows the relationship between the lattice constant and the thermal resistivity for InGaAs and for InGaP;

FIG. 3 is a cross section of a device that was manufactured according to the process of manufacturing the HBT of the first exemplary embodiment;

FIG. 4 is a cross section of a device that was manufactured according to the process of manufacturing the HBT of the first exemplary embodiment;

FIG. 5 is a cross section of a device that was manufactured according to the process of manufacturing the HBT of the first exemplary embodiment;

FIG. 6 is a cross section of a device that was manufactured according to the process of manufacturing the HBT of the first exemplary embodiment;

FIG. 7 is a cross section of a device that was manufactured according to the process of manufacturing the HBT of the first exemplary embodiment;

FIG. 8 is a cross section of a device that was manufactured according to the process of manufacturing the HBT of the first exemplary embodiment;

FIG. 9 is a cross section of a device that was manufactured according to the process of manufacturing the HBT of the first exemplary embodiment;

FIG. 10 is a cross section of an HBT of the first exemplary embodiment;

FIG. 11 is a block diagram showing an example of a system configuration for a portable telephone;

FIG. 12 is a view showing a composition of an amplifier;

FIG. 13 is a cross section of an HBT of a second exemplary embodiment; and

FIG. 14 shows the relationships between the buffer thickness of the buffer layer and the lattice constant and between the buffer thickness and the thermal resistivity for a HBT of the second exemplary embodiment.

### DETAILED DESCRIPTION OF THE INVENTION

It is to be understood that the figures and descriptions of the present invention have been simplified to illustrate elements that are relevant for a clear understanding of the present invention, while eliminating, for purposes of clarity, other elements that may be well known. Those of ordinary skill in the art will recognize that other elements are desirable and/or required in order to implement the present invention. However, because such elements are well known in the art, and because they do not facilitate a better understanding of the present invention, a discussion of such elements is not provided herein. The detailed description will be provided hereinbelow with reference to the attached drawings.

The semiconductor device according to the present invention preferably includes semiconductor thin-film crystals, each of which having a different lattice constant in a direction parallel to the above-mentioned substrate crystal plane from that of the above-mentioned substrate, that are deposited on the substrate crystal with a buffer layer interposed therebetween. The semiconductor device is characterized in that the lattice constants of the buffer layers are changed between the lattice constant of the substrate crystal and the lattice constant of the semiconductor thin-film crystal as a result of a compositional change of the buffer layers. Also, the buffer layers preferably comprise alloy compound semiconductor layers with thermal resistivities that increase with increasing lattice constant and alloy compound semiconductor layers with thermal resistivities that decrease with increasing lattice constant.

The present invention also preferably provides a semiconductor device formed by employing the lattice-mismatched system semiconductor thin-film crystal layered product such that semiconductor thin-film crystals, each of which having a different lattice constant in a direction parallel to the above-mentioned substrate crystal plane from that of the above-mentioned substrate, are deposited on a substrate crystal with a buffer layer interposed therebetween. The semiconductor devices are characterized in that the buffer layer comprises a plurality of ternary alloy compound semiconductor layers, each of which has a different set of constituent elements. The device is further characterized in that the ternary alloy compound semiconductor layer having a higher content of a binary alloy compound semiconductor whose lattice constant is closest to that of the above-mentioned substrate crystal, among the binary alloy compound semiconductors that each constitute the above-mentioned ternary alloy compound semiconductor layer, is placed at a position closer to the above-mentioned substrate crystal. Further, the ternary alloy compound semiconductor layer having a higher content of a binary alloy compound semiconductor whose lattice constant is closest to that of the above-mentioned semiconductor thin-film crystal, among the above-mentioned binary alloy compound semiconductors, is placed at a position closer to the above-mentioned semiconductor thin-film crystals.

It should be noted that the compositional change of said compound semiconductor material that causes the lattice constant and the thermal resistivity of the buffer layer to be changed may be achieved in any one of the following ways: (1) thin-film layers, each of which has a predetermined composition, are deposited; (2) the composition of the said compound semiconductor material is varied continuously over the entire buffer layer; and (3) stacked thin-film layers, each of which has a predetermined composition, and a layer of the compound semiconductor material with a continuously varied composition are both employed.

The lattice-strain-relaxed material that bridges from the GaAs substrate to the InP system compound semiconductor material may be any of the following materials.

For the material whose thermal resistivity increases with increasing lattice constant, there are an InGaAs system material (precisely, InₓGa₁₋ₓAs with 0≦x<0.5), an InAlAs material (InₓAl₁₋ₓAs with 0≦x<0.5), a GaAsSb system material (GaAs₁₋ₓSbₓ with 0≦x<0.5), and an AlAsSb system material (AlAs₁₋ₓSbₓ with 0≦x<0.5), etc. These material systems are provided on the GaAs substrate side. On the other hand, for the material whose thermal resistivity decreases with increasing lattice constant, there are available an InGaP system material (precisely, InₓGa₁₋ₓP with 0.5<x≦1), an InAlP system material (InₓAl₁₋ₓP with 0.5<x≦1), etc. These material systems are provided on the HBT side.

It should be noted here that, as described in detail for the material systems, there exists, in the same material system, a region of content where the thermal resistivity increases and a region of content where the thermal resistivity decreases within increasing lattice constant depending on from which substrate and to which material system the lattice constant thereof is intended to be changed. For example, InₓGa₁₋ₓAs becomes a material whose thermal resistivity increases in a region of 0≦x<0.5. Hereafter, in the description of the present invention, any material described simply as the InGaAs system material (etc.) without further detailed information or other indication is meant to include InGaAs and other materials with a composition such as that which matches the objects or intended purposes of the present invention.

In the InP system compound semiconductor material, the following measure is preferably employed to achieve a lattice-strain-relaxed buffer layer whose lattice constant is changed gradually from GaAs to InP without increasing the thermal resistivity, which is the above-mentioned object. That is, the present invention employs the lattice-strain-relaxed buffer layer formed by combining a material, for example InGaAs, whose thermal resistivity increases with increasing lattice constant and a material, for example InGaP, whose thermal resistivity decreases with increasing lattice constant when the lattice constant of the buffer layer is changed between the lattice constant of GaAs and the lattice constant of InP by changing its composition. If a certain material, for example InAlAs, is used instead of InGaAs, the same effect can be obtained because the relationship between the lattice constant and the thermal resistivity of the material when the In content is changed is equal to that of InGaAs.

The principle of the present invention may be widely applied to reduce the thermal resistivity of the lattice-strain-relaxed buffer layer for bridging two semiconductor materials each having a different lattice constant. For example, for the lattice-strain-relaxed buffer whose lattice constant is changed from InP to GaSb, the idea suggests that a lattice-strain-relaxed buffer be employed that is formed by combining a material, for example, InPSb system materials (InP₁₋ₓSbₓ with 0≦x<0.5), whose thermal resistivity increases with increasing lattice constant when the lattice constant is changed between the lattice constant of InP and the lattice constant of GaSb by changing its composition and a material, for example, InGaAs system materials (InₓGa₁₋ₓAs with 0≦x<0.5), whose thermal resistivity decreases with increasing lattice constant in the same situation.

Note that the present invention may be applied to any semiconductor device that is formed by employing the lattice-mismatched system semiconductor thin-film crystal, layered product such that semiconductor thin-film crystals each of which having a different lattice constant in a direction parallel to the substrate crystal plane from that of the substrate, were deposited thereon. Therefore, it is naturally possible to build semiconductor elements other than the exemplified HBT, for example, a high mobility transistor (e.g., a high mobility compound semiconductor element such as the so-called “HEMT”) or a laser element (especially a high-power laser element), etc. on the buffer layer according to the present invention as well. By virtue of this form, a prescribed effect can be achieved.

First Exemplary Embodiment

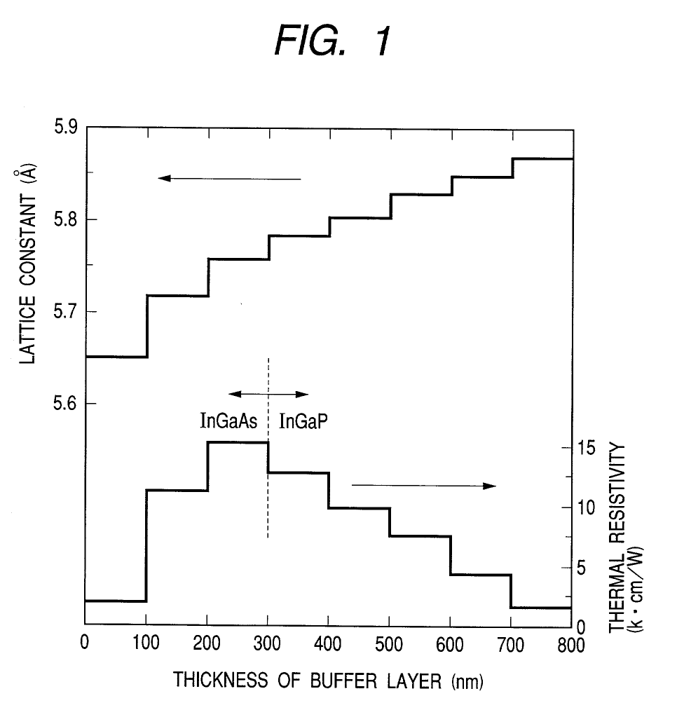

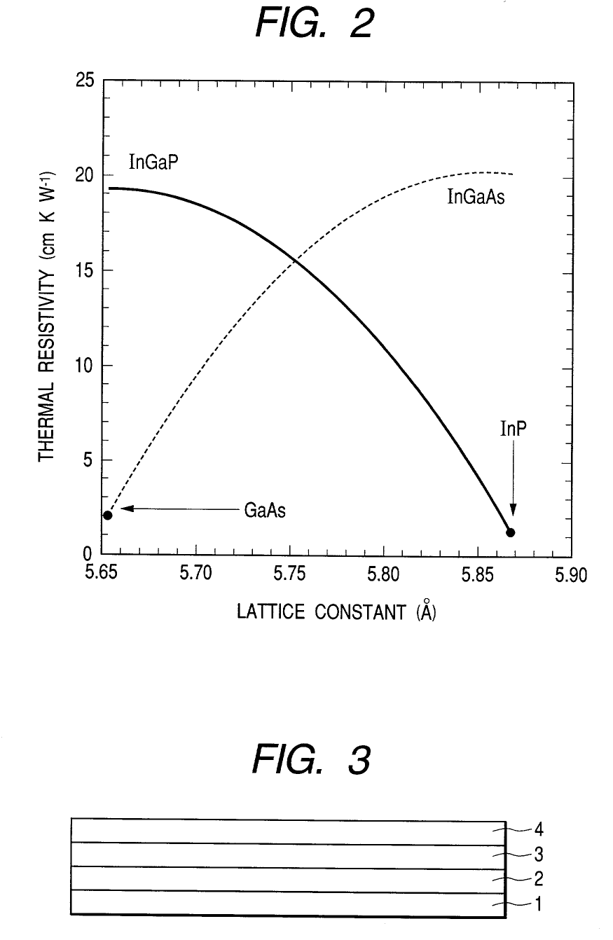

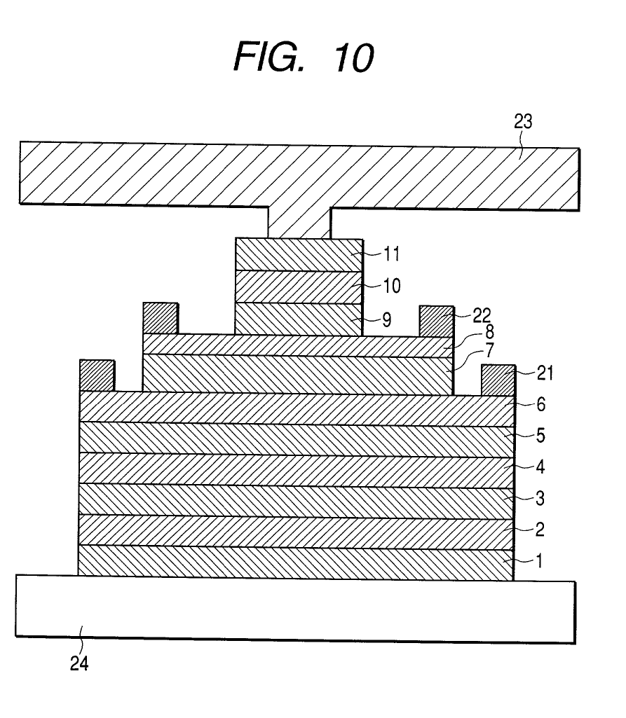

The first exemplary embodiment according to the present invention will be described with reference to FIG. 1 through FIG. 10. FIG. 1 shows the relationship between the buffer thickness and the lattice constant and between the buffer thickness and the thermal resistivity of the buffer layer of the HBT. FIG. 2 shows the relationship between the lattice constant and the thermal resistivity for InGaAs and InGaP, and FIG. 3 through FIG. 9 are cross sections of a device illustrating the sequential steps of a manufacturing process according to this example. Finally, FIG. 10 is a cross section of the HBT according to this embodiment.

With reference to FIG. 3 through FIG. 9, the manufacturing process of this example will now be described. Initially, by using an MBE (Molecular Beam Epitaxy) apparatus, an undoped GaAs buffer layer 2 of a 0.1 μm thickness is formed on a semi-insulating GaAs substrate 1. Then an undoped InₓGa₁₋ₓAs buffer layer 3 of a 0.2 μm thickness is deposited thereon, and an undoped In_{y}Ga_{1-y}P buffer layer 4 of a 0.5 μm thickness is deposited on these layers. Here, in the above-mentioned undoped InₓGa₁₋ₓAs buffer layer 3, the x is changed stepwise: first x=0.15 and then x=0.23. The thickness of each stepped layer is specified to be 0.1 μm. Moreover, in the above-mentioned undoped In_{y}Ga_{1-y}P buffer layer 4, the y is changed stepwise: x=0.80, 0.85, 0.90, 0.95, and 1.0 sequentially (FIG. 3). The thickness of each stepped layer is specified to be 0.1 μm.

The configurations of the buffer layers 2, 3, and 4 as mentioned above are important in this example. Incidentally, for the buffer layer thus configured, a thickness in the range of about 0.5-1.0 μm or so is preferably used at present. A buffer layer of an even thinner thickness can also be used. Thinner layers are advantageous from a manufacturing point of view. Moreover, it is suitable that the thickness of each thin layer (each stepped layer) that constitutes the buffer layer is, from a practical standpoint, in a range of at least about 0.08-0.12 μm.

The thicknesses of these thin layers are preferably selected according to how the buffer layer is divided into the stepped layers, each having a different composition. If the division is coarse, the thickness of each thin layer is made thicker, whereas if the division is fine, the thickness of each thin layer is made thinner. An ultimate form of the latter, that is, an extreme case where the step of the division is extremely fine and the thickness of each thin layer is made to be extremely thin corresponds to a continuous variation of the composition that will be exemplified as the second embodiment. FIG. 1 shows the relationship between the buffer thickness of the buffer layer and the lattice constant and between the buffer thickness and the thermal resistivity.

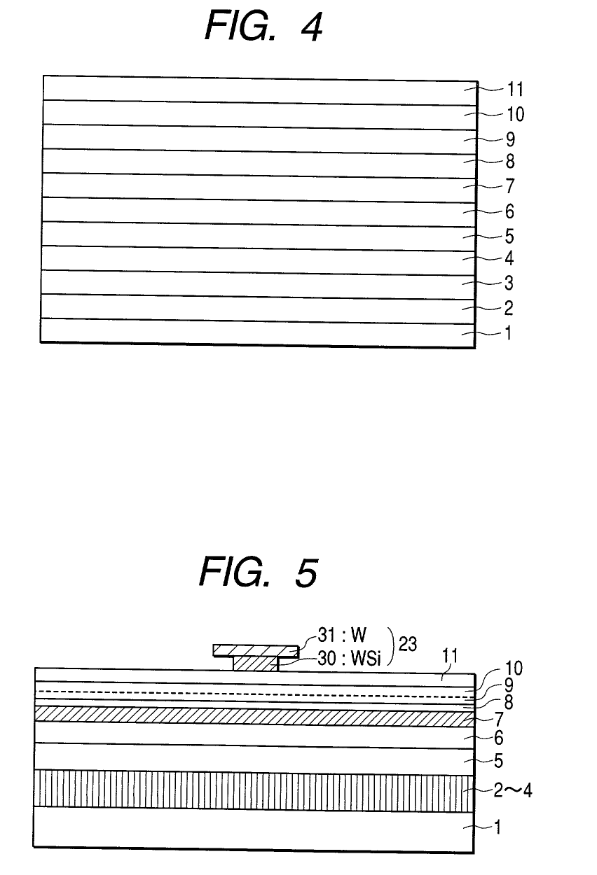

On the layered product thus prepared, a semiconductor element part of the well-known HBT structure lattice-matched to InP is built. An example of this HBT structure may comprise the following layer configuration, by way of example. Other configurations may be also adopted. A layered product comprising: an n-type InP sub-collector layer 5 (dopant concentration: 3×10¹⁹ cm⁻³) of a 300 nm thickness; p-type InGaAs base layer 7 (dopant concentration: 2.5×10¹⁹ cm⁻³) of a 50 nm an n-type InGaAs collector layer 6 (dopant concentration: 2×10¹⁶ cm⁻³) of a 300 nm thickness; an undoped InGaAs spacer layer 8 of a 5 nm thickness; an n-type InP emitter layer 9 (dopant concentration: 5×10¹⁷ cm⁻³) of a 50 nm thickness; an n-type InP emitter layer 10 (dopant concentration: 2×10¹⁹ cm⁻³) of a 20 nm thickness; and an n-type InGaAs emitter cap layer 11 (dopant concentration: 4×10¹⁹ cm⁻³) of a 20 nm thickness may be deposited sequentially (FIG. 4).

On the semiconductor layered product thus formed, a WSi (tungsten silicide) layer 30 and a W (tungsten) layer 31 serving as an emitter electrode 23 are deposited sequentially for a 350 nm thickness and for a 150 nm thickness, respectively. The emitter electrode 23 is processed, for example, by ECR etching using a common photoresist as a mask. By making the electrode undergo “overetching” in the etching process, the WSi layer 30 is side-etched to effect formation of an undercut shape (FIG. 5).

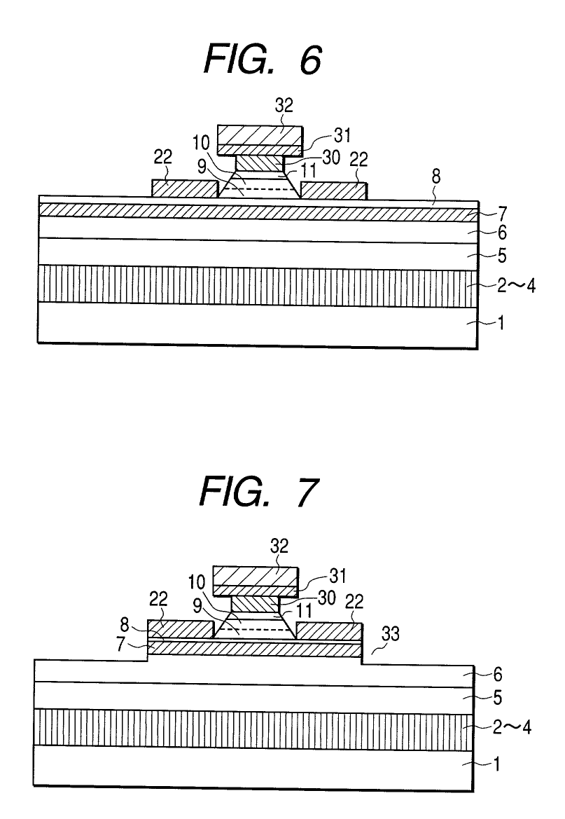

In FIG. 6 through FIG. 9 below, the layers 2, 3, and 4 that constitute the entire buffer layer are shown as one layer for clarity. Next, by using the emitter electrode 23 thus formed as a mask region, the emitter cap layer 11 and the emitter layers 10, 9 are processed by common wet etching. Successively, a base electrode material is evaporated and a base electrode 22 of a desired shape is formed by the so-called lift-off method (FIG. 6). The base electrode 22 is made up of, for example, a layered product consisting of Pt/Ti/Mo/Ti/Pt/Au wherein the lowest layer is formed with Pt. Note that concurrently with the formation of the base electrode 22, a layer of the same material 32 as the base electrode 22 is deposited on the W (tungsten) layer 31 which constitutes the emitter electrode 23.

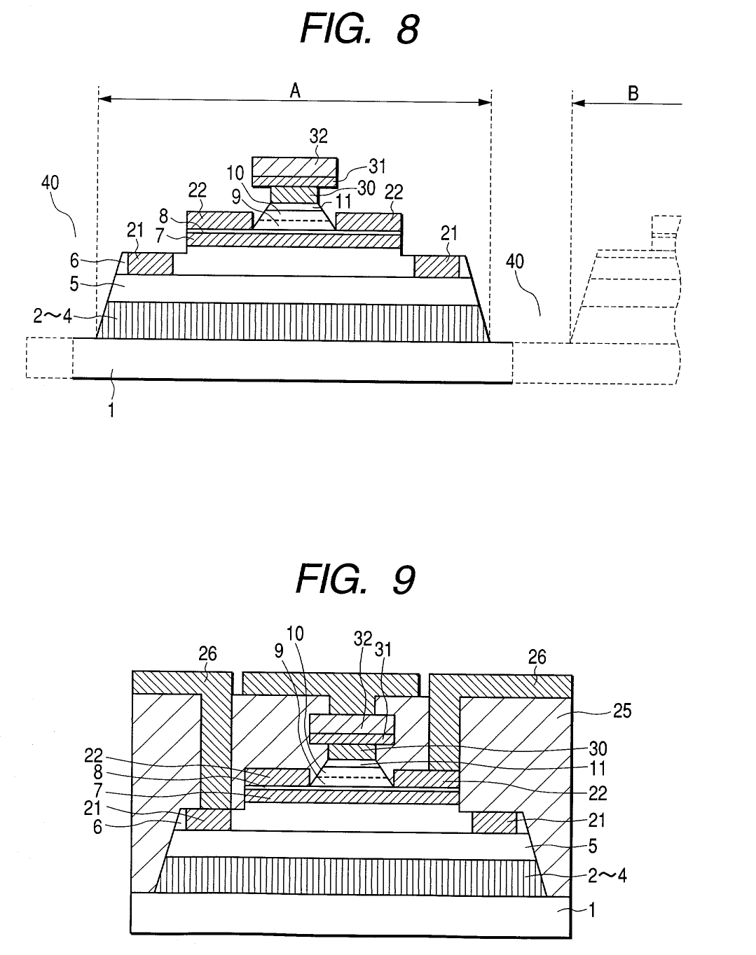

Next, while the emitter region is covered with the photoresist, the base of the base layer 7 is etched to form a mesa 33 by using the base electrode region as a mask region (FIG. 7). Further, the collector layer 6 is etched only for a region where a collector electrode 21 is to be formed. Then, a layered product of Ti/Pt/Au is deposited on this region, and the collector electrode 21 of a desired shape is formed from this layered product by means of the lift-off method. In addition, the area surrounding the sub-collector layer 5 is etched away to achieve element isolation. The numeral 40 designates a trench for isolating individual elements (FIG. 8). In FIG. 8, a geometry of a plurality of semiconductor elements that were formed on a single wafer is shown. In other figures, only the region of a single transistor is shown. A region “A” of FIG. 8 designates one of these transistor regions and a region “B” designates another semiconductor element region that was formed, being isolated from this region A by an isolation trench 40. The kind of element that resides in this region B is determined by the circuit structure that the semiconductor integrated circuit assumes.

Next, an interlayer insulating film 25 is formed, and subsequently a contact hole is formed on this interlayer insulating film 25 and wiring 26 is provided with the use of a conductive material such as Au (FIG. 9).

FIG. 10 is a conceptual cross section of the HBT formed in the same manner. In the example of FIG. 10, the collector electrode 21 is formed on the upper side of the layer 6. Note that a detailed structure of the emitter electrode 23 is omitted, and the electrode is illustrated as an integral structure. The emitter electrode 23 is formed in the same manner as that of FIG. 9. Note that specific compositions of the HBT may take other form than depicted in this example.

Here, the thermal resistance of the buffer portion of the fabricated HBT are compared to those of HBTs that have only InGaP or only InGaAs used as the buffer material, respectively. Table 1 compares the thermal resistivities of these buffer layers. In each field of the columns for the prior art devices in Table 1, the ratio of the In content and the thickness of each stepped layer that constitutes the buffer layer are depicted. Moreover, in each field of the column for the device according to the present invention, the ratio of the In content and the thickness of each stepped layer illustrated above of InGaAs and InGaP that constitute the buffer layer are depicted. Further, in each of the examples, the total of the thermal resistivities for each stepped layer of said buffer layer is shown in the lowest field of each column as a “simple total of buffer thermal resistivities.” Note that the unit of the thermal resistivity is cmKW⁻¹, and the values are for bulk crystals.

TABLE 1

| Prior Art 1 | | Prior Art 2 | | Present Invention | |
|---|---|---|---|---|---|
| (with only InGaP) | | (with only InGaAs) | | (InGaAs + InGaP) | |
| Layer Configuration | Thermal | Layer Configuration | Thermal | Layer Configuration | Thermal |
| (In content) | Resistivity | (In content) | Resistivity | (In content) | Resistivity |
| InP, 100 nm | 1.47 | InGaAs(0.5) | 21 | InP, 100 nm | 1.47 |
| | | 100 nm | | | |
| InGaP(0.95) | 4.5 | InGaAs(0.45) | 20.5 | InGaP(0.95), 100 nm | 4.5 |
| 100 nm | | 100 nm | | | |
| InGaP(0.90) | 7.5 | InGaAs(0.40) | 20 | InGaP(0.90), 100 nm | 7.5 |
| 100 nm | | 100 nm | | | |
| InGaP(0.85) | 10 | InGaAs(0.35) | 19 | InGaP(0.85), 100 nm | 10 |
| 100 nm | | 100 nm | | | |
| InGaP(0.80) | 13 | InGaAs(0.30) | 18 | InGaP(0.80), 100 nm | 13 |
| 100 nm | | 100 nm | | | |
| InGaP(0.73) | 16 | InGaAs(0.23) | 15.5 | InGaAs(0.23), 100 nm | 15.5 |
| 100 nm | | 100 nm | | | |
| InGaP(0.65) | 18 | InGaAs(0.15) | 11.5 | InGaAs(0.15), 100 nm | 11.5 |
| 100 nm | | 100 nm | | | |
| InGaP(0.5) | 19.5 | GaAs buffer, | 2.14 | GaAs buffer, | 2.14 |
| 100 nm | | 100 nm | | 100 nm | |
| GaAs substrate | 2.14 | GaAs substrate | 2.14 | GaAs substrate | 2.14 |
| Simple total of | 90.0 | simple total of buffer | 127.6 | simple total of buffer | 65.6 |
| buffer thermal | | thermal resistivities | | thermal resistivities | |
| resistivities | | | | | |

Thermal resistivities are bulk values in units of (cmKW⁻¹).

Because the thickness of each layer is the same for the three buffers, the thermal resistivities of the buffer layers can be compared with one another simply with the totals thermal resistivities of the layers. As shown in Table 1, the total thermal resistivities of the buffer according to the present invention is approximately 66K·cm/W, whereas that of the buffer composed of only InGaP materials is approximately 90K·cm/W and that of the buffer composed of only InGaAs materials is approximately 128K·cm/W. From these results, it can be fully understood that the thermal resistivity of the buffer according to the present invention is the lowest of the three and that it has a considerable difference from those of other buffers.

Heat generated immediately under the emitter when the HBT is being operated is radiated from a heat sink 24 through the emitter electrode 23 and the buffer layers 2, 3, and 4. Therefore, an HBT whose buffer layer has the lowest thermal resistivity according to the present invention has improved heat radiation characteristics and has a reduced fear of thermal runaway. Accordingly, the present invention may be used to fabricate an HBT with improved heat radiation characteristics on a low-priced GaAs substrate. Even if the wiring metal formed on the backside of the substrate is utilized to radiate heat instead of the heat sink 24, the effect is the same as described above.

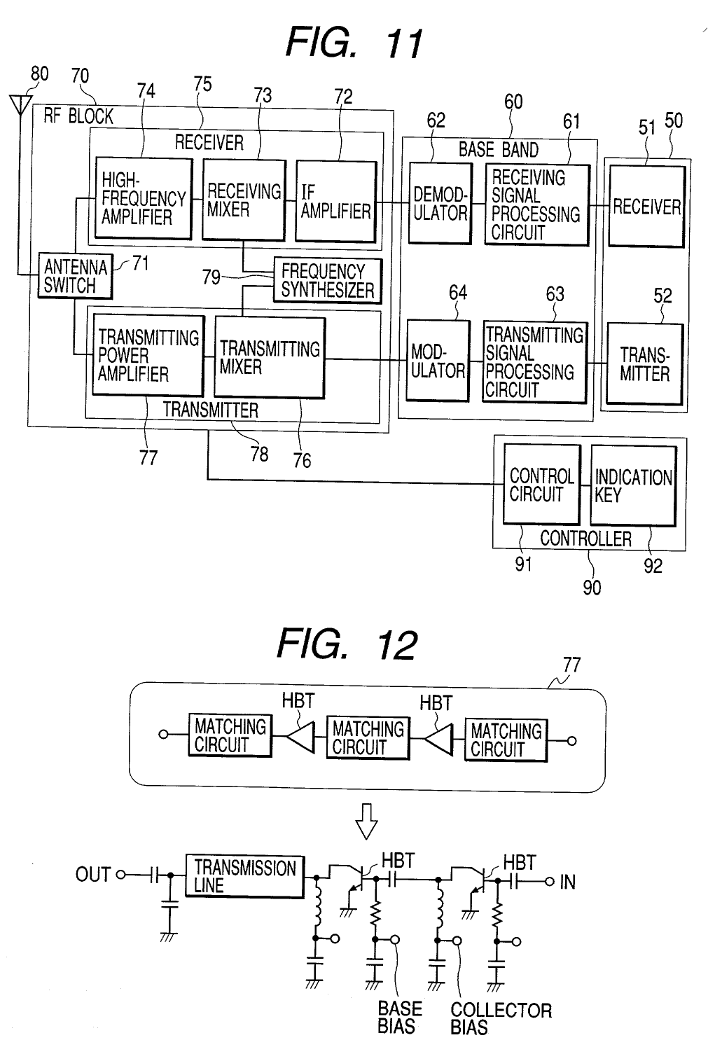

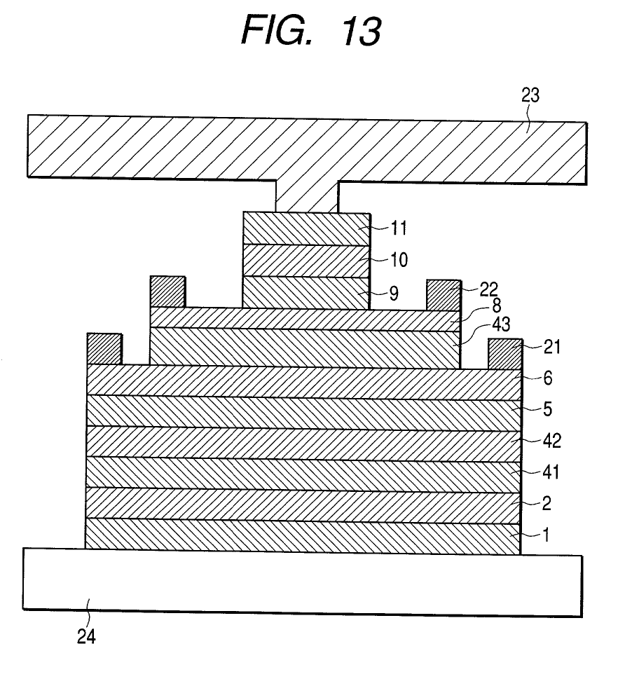

Application examples of this HBT are shown in FIG. 11 and FIG. 12. FIG. 11 is a block diagram showing a system configuration for an electronic device into which the HBT of the first embodiment may be built. Here, the system configuration of a portable telephone is shown. The HBT of this embodiment is used for a high-frequency transmitting power amplifier 77. FIG. 12 illustrates a block diagram of this high-frequency transmitting power amplifier 77 and a specific example of a circuit to implement the amplifier. A transistor designated as “HBT” in FIG. 12 is the HBT according to the present invention.

The portable telephone preferably comprises: a handset 50 comprising a receiver 51 and a transmitter 52; a base band 60 comprising a receiving signal processing circuit 61, a demodulator 62, a transmitting signal processing circuit 63, and a modulator 64; a controller 90 comprising a control circuit 91, and an indication key 92; and an RF Block 70.

The RF Block 70 has an antenna switch 71, which is preferably connected to: a receiver 75 comprised of a high-frequency amplifier 74, a receiving mixer 73, and an IF amplifier 72; a transmitter 78 comprised of the transmitting power amplifier 77 and a transmitting mixer 76; and an antenna 80. Also, the receiving mixer 73 and the transmitting mixer 76 are connected to a frequency synthesizer 79.

Because the HBT used in the transmitting power amplifier 77 has improved heat radiation characteristics in the buffer structure, a portable telephone with a stable transmission characteristic and reduced likelihood of thermal runaway may be fabricated.

This embodiment exemplified a semiconductor device wherein the In contents of the InₓGa₁₋ₓAs buffer layer 3 and of the In_{y}Ga_{1-y}P buffer layer 4 are changed stepwise.

However, the same effect can be obtained with the so-called “linear graded buffers” wherein the In content is varied continuously in the layers 3, 4.

Tables 2 and 3 provide lists of the lattice-strain-relaxed materials comprising the following groups of materials: (1) materials having thermal resistivity that increases with increasing lattice constant, such as InGaAs, InAlAs, GaAsSb, AlAsSb, and (2) materials having thermal resistivity that decreases with increasing lattice constant, such as InGaP and InAlP. In each entry of the tables, the lattice constants of binary compound semiconductor materials that constitute respective alloy material and materials that should be placed on the GaAs substrate side or on the InP side are shown. According to the objects of the present invention, materials may be selected from among these of materials.

TABLE 2

| Variation caused by | | | | |
|---|---|---|---|---|
| increase in lattice | | | | |
| constant | | Material | GaAs side | InP side |
| Increase in thermal | to be | InGaAs = GaAs(5.6532Å) − InAs(6.0583Å) | GaAs | In_{0.53}Ga_{0.47}As |
| resistivity | deposited | | | |
| 1 | on GaAs | InAlAs = AlAs(5.6600Å) − InAs(6.0583Å) | AlAs | In_{0.52}Al_{0.48}As |
| 1 | side | GaAsSb = GaAs(5.6532Å) − GaSb(6.0959Å) | GaAs | GaAs_{0.51}Sb_{0.49} |
| 1 | | AlAsSb = AlAs(5.6600Å) − AlSb(6.1360Å) | AlAs | AlAs_{0.55}Sb_{0.45} |
| Decrease in thermal | to be | | | |
| resistivity | deposited | InGaP = GaP(5.4512Å) + InP(5.8687Å) | In_{0.48}Ga_{0.52}P | InP |
| 1 | on HBT | InAlP = AlP(5.4670Å) + InP(5.8687Å) | In_{0.46}Al_{0.54}P | InP |
| | side | | | |

TABLE 3

| Variation caused by increase | | | GaSb, |
|---|---|---|---|
| in lattice constant | Material | InP side | InAs side |
| Increase in thermal resistivity | InPSb = InP(5.8687Å) + InSb(6.4794Å) | InP | InP_{0.63}Sb_{0.37} |
| Decrease in thermal | InGaAs = GaAs(5.6532Å) + InAs(6.0583Å) | In_{0.53}Ga_{0.47}As | InAs |
| resistivity | | | |
| 1 | InAlAs = AlAs(5.6600Å) + InAs(6.0583Å) | In_{0.52}Al_{0.48}As | InAs |
| 1 | GaAaSb = GaAs(5.6532Å) + GaSb(6.0959Å) | GaAs_{0.51}Sb_{0.49} | GaSb |
| 1 | AlAsSb = AlAs(5.6600Å) + AlSb(6.1360Å) | AlAs_{0.55}Sb_{0.45} | AlSb |

Table 2 shows a list of the lattice-strain-relaxed buffer materials for bridging from GaAs to InP. Table 3 shows a list of the lattice-strain-relaxed buffer materials for bridging from InP to GaSb and InAs system elements. The present invention can be embodied by selecting materials from among these exemplary materials according to the objects of the present invention.

The groups of usable compound semiconductor materials such as these are also applicable to a form of the second embodiment (described below).

In addition to the semiconductor element that is built on the lattice-strained-relax buffer layer described above, i.e., the HBT in this example, it is also possible to build a semiconductor element part, such as a high mobility transistor (e.g., a high-mobility compound semiconductor element such as the so-called HEMT) or a laser element and to still achieve the desired effect.

Second Exemplary Embodiment

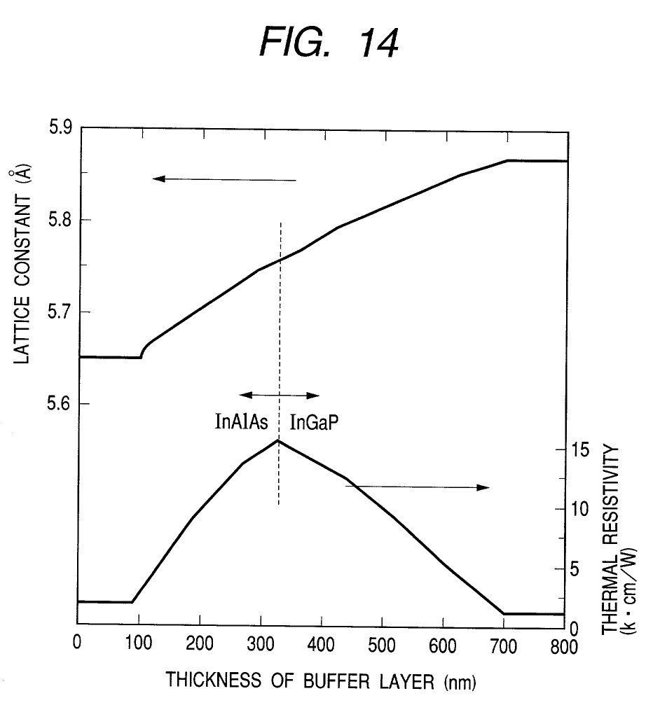

The second embodiment according to the present invention will now be described referring to FIG. 2 and FIGS. 13-14.

For the manufacturing process, FIG. 13 is now used for reference. By using an MBE apparatus, the undoped GaAs buffer layer 2 of a 0.1 μm thickness is deposited on the semi-insulating GaAs substrate 1, then an undoped InₓAl₁₋ₓAs buffer layer 41 of a 0.2 μm thickness (mole fraction x being varied from 0 to 0.25 continuously) is deposited thereon, and an undoped In_{y}Ga_{1-y}P buffer layer 42 of a 0.5 μm thickness (mole fraction y being varied from 0.75 to 1.0 continuously) is deposited on these layers.

Further on this layered product, a common HBT structure lattice-matched to InP is formed that consists of, for example: the n-type InP sub-collector layer 5 (dopant concentration: 3×10¹⁹ cm⁻³) of a 300 nm thickness; the n-type InGaAs collector layer 6 (dopant concentration: 2×10¹⁶ cm⁻³) of a 300 nm thickness; a p-type GaAsSb base layer 43 (dopant concentration: 2.5×10¹⁹ cm⁻³) of a 50 nm thickness; the undoped InGaAs spacer layer 8 of a 5 nm thickness; the n-type InP emitter layer 9 (dopant concentration: 5×10¹⁷ cm⁻³) of a 50 nm thickness; the n-type InP emitter layer 10 (dopant concentration: 2×10¹⁹ cm⁻³) of a 20 nm thickness; and the n-type InGaAs emitter cap layer 11 (dopant concentration: 4×10¹⁹ cm⁻³) in succession.

On the multi-layered crystals thus fabricated, a WSi layer and a W layer that serve as the emitter electrode are deposited sequentially for a 35 nm thickness and for a 150 nm thickness, respectively. Then, by using a common photoresist mask, the said electrode material is etched to a desired shape. Next, in the same manner as in the first embodiment, by using the emitter electrode 23 thus formed as a mask, a further etching process is used, and by an evaporation method and the lift-off method, the Pt/Ti/Mo/Au system base electrode 22 is formed.

Next, after the emitter region is covered with a photoresist, base mesa etching is performed to etch only a portion where the collector electrode 21 is to be formed. Then, the collector electrode 21 is formed on said region with a Ti/Pt/Au system material.

In the same manner as in the first embodiment, the etching for element isolation and the formation of the interlayer insulating layer film are finally conducted, and a process for the wiring is subsequently employed to fabricate the HBT device shown in FIG. 13. Incidentally, a trench for element isolation is not shown explicitly in FIG. 13. Although FIG. 13 shows only the HBT, in many cases a number of semiconductor element parts are formed, being integrated, on a single wafer. In such cases, to electrically isolate the HBT from the other semiconductor element parts, a trench is usually formed. Note also that a detailed structure of the emitter electrode 23 is omitted and is exemplified as an integral structure. The emitter electrode 23 is formed, for example, in the same manner as that of FIG. 9.

Comparing the thermal resistivity of the buffer portion of the HBT thus fabricated with those of the buffer portions that are composed of only InGaP materials and of only InAlAs materials, respectively, the total thermal resistivities of the buffer according to the present invention is approximately 60K·cm/W, whereas that of the buffer composed of only InGaP materials is approximately 90K·cm/W and that of the buffer composed of only InGaAs materials is approximately 90K·cm/W. From these results, it is shown that the thermal resistivity of the buffer according to the present invention is reduced. Therefore, the present invention may be used to fabricate an HBT on a low-priced GaAs substrate.

Moreover, in this embodiment, because the high-resistivity InₓAl₁₋ₓ As layer is used for the buffer layer, the elements can be electrically isolated even if the element isolation trench does not reach the substrate. Based on this, the depth of the element isolation trench can be shallow and, hence, the wiring process may be easier to employ. On the other hand, if the layer that has a higher Al content is exposed, there arises potential disadvantages such as an increased difficulty of a protection film fabrication process. Therefore techniques of element isolation may be properly selected according to the needs of the user.

In this embodiment, the In contents of the InₓAl₁₋ₓAs buffer layer 41 and of the In_{y}Ga_{1-y}P buffer layer 42 were varied continuously. However, adoption of the so-called step-graded buffer wherein the In content is changed stepwise can achieve the same effect.

The HBT structure used in this embodiment is one example. It should be noted that use of other materials as well as other structures can achieve the effect of the present invention on the condition that the element concerned is an HBT that employs the lattice-mismatched system semiconductor thin-film crystal layered product, wherein each constituent thin-film crystal is different from the substrate material in the lattice constant. Use of the material lattice-matched to InP is not necessarily mandatory, and the same effect of the present invention can be achieved with a different material. Naturally, it is also possible to build semiconductor element parts, for example, a high mobility transistor part (e.g., the high mobility compound semiconductor elements such as the so-called HEMT) other than the HBT of this example and to achieve a prescribed effect.

Moreover, in the first and second exemplary embodiments, the following materials were used as the materials for serving as a bridge between the lattice constant of GaAs and the that of InP: (1) for the alloy compound semiconductor layer whose thermal resistivity increases with increasing lattice constant, InₓGa₁₋ₓAs or InₓAl₁₋ₓAs; and (2) for the alloy compound semiconductor layer whose thermal resistivity decreases with increasing lattice constant, In_{y}Ga_{1-y}P. However, as described above, for materials other than these materials, there are GaAsSb and AlAsSb as the alloy compound semiconductor layer whose thermal resistivity increases with increasing lattice constant and InAlP as the alloy compound semiconductor layer whose thermal resistivity decreases with increasing lattice constant. Since these materials are applicable as well, the use of any combination of these materials makes no difference in the effect of the present invention. Here, the use of GaAsSb or AlAsSb brings about additional merit in that the thickness of the buffer layer is more uniform.

An electronic device into which the HBT of this second embodiment is built can be realized with the composition of FIG. 11 and FIG. 12 similarly with the case of the first embodiment. The HBT of this embodiment is used for the high-frequency transmitting power amplifier 77 in the same way as the foregoing example.

Here, since the HBT used in the transmitting power amplifier 77 has a buffer structure with improved heat radiation characteristics, a portable telephone with a reduced likelihood of thermal runaway and with a stable transmission characteristic can be fabricated.

Naturally, the present invention can be applied to the HEMT (high electron mobility transistor) and a field effect transistor, that are specified to deliver a high output, as well as to a high-output laser element, all of which present heat generation problems, to effect improvement of their heat radiation characteristic. Moreover, the present invention can be applied to electronic apparatuses such as a millimeter wave radar with a decreased incidence of thermal runaway.

As described in detail in the foregoing, according to the present invention, the heat radiation of the semiconductor device to the substrate side that employed the lattice-mismatched system semiconductor thin-film crystal layered product such that at least one thin-film crystal is different in the lattice constant from the substrate can be improved. Therefore, high-performance semiconductor devices can be fabricated on a low-priced substrate that can be enlarged in diameter, without being constrained for the lattice constant. As a result, for the semiconductor device and the electron device that uses it, making them more efficient and making them less expensive are compatible.

The present invention can provide a compound semiconductor device that is inexpensive and can be mass-produced. Further, the present invention can provide a compound semiconductor device that can secure the characteristic of its semiconductor element stably and that is inexpensive and can be mass-produced.

Nothing in the above description is meant to limit the present invention to any specific materials, geometry, or orientation of parts. Many part/orientation substitutions are contemplated within the scope of the present invention. The embodiments described herein were presented by way of example only and should not be used to limit the scope of the invention.

Although the invention has been described in terms of particular embodiments in an application, one of ordinary skill in the art, in light of the teachings herein, can generate additional embodiments and modifications without departing from the spirit of, or exceeding the scope of, the claimed invention. Accordingly, it is understood that the drawings and the descriptions herein are proffered by way of example only to facilitate comprehension of the invention and should not be construed to limit the scope thereof.

What is claimed is:

1. A semiconductor device, comprising:
a substrate crystal plane;
a buffer layer; and
thin-film crystals deposited on said substrate crystal with said buffer layer interposed therebetween, wherein each of said thin-film crystals has a lattice constant in a direction parallel to said substrate crystal plane that is different from a lattice constant of said substrate crystal,
further wherein said buffer layer comprises
first alloy compound semiconductor layers with thermal resistivities that increase with increasing lattice constant when the lattice constant thereof is changed between the lattice constant of said substrate crystal and the lattice constant of said semiconductor thin-film crystal by changing the composition of said first alloy compound
and second alloy compound semiconductor layers with thermal resistivities that decrease with increasing lattice constant when the lattice constant thereof is changed between the lattice constant of said substrate crystal and the lattice constant of said semiconductor thin-film crystal by changing the composition of said second alloy compound.

2. A semiconductor device according to claim 1, wherein
at least said first alloy compound semiconductor layer is formed using a plurality of alloy compound semiconductor thin-film layers, each with thermal resistivities that increase with increasing lattice constant.

3. A semiconductor device according to claim 1, wherein
at least said second alloy compound semiconductor layer is formed using a plurality of alloy compound semiconductor thin-film layers, each with thermal resistivities that decrease with increasing lattice constant.

4. A semiconductor device according to claim 2, wherein
at least said second alloy compound semiconductor layer is formed using a plurality of alloy compound semiconductor thin-film layers, each with thermal resistivities that decrease with increasing lattice constant.

5. A semiconductor device according to claim 1, wherein
at least said first alloy compound semiconductor layer is an alloy compound semiconductor layer with a thermal resistivity that varies continuously within the first alloy compound semiconductor layer.

6. A semiconductor device according to claim 4, wherein
at least said second alloy compound semiconductor layer is an alloy compound semiconductor thin-film layer with a thermal resistivity that varies continuously within the second alloy compound semiconductor layer.

7. A semiconductor device according to claim 5, wherein
at least said second alloy compound semiconductor layer is an alloy compound semiconductor thin-film layer with a thermal resistivity that varies continuously within the second alloy compound semiconductor layer.

8. A semiconductor device according to claim 1, wherein
said substrate crystal is GaAs,
the lattice constant of said semiconductor thin-film crystals are matched to that of InP,
said first alloy compound semiconductor layer is either an InGaAs system material or an InAlAs system material, and
said second alloy compound semiconductor layer is an InGaP system material.

9. A semiconductor device formed by employing a lattice-mismatched system semiconductor thin-film crystal layered product, comprising:
a substrate crystal plane;
a buffer layer; and
thin-film crystals deposited on said substrate crystal with said buffer layer interposed therebetween, wherein each of said thin-film crystals has a lattice constant in a direction parallel to said substrate crystal plane that is different from a lattice constant of said substrate crystal;
wherein said buffer layer is comprised of a plurality of ternary compound semiconductor layers including
a first ternary compound semiconductor layer that has a higher content of a binary compound semiconductor whose lattice constant is closest to the lattice constant of said substrate crystal, among binary compound semiconductors that each constitute said ternary compound semiconductor layers, wherein said first ternary compound is placed at a position closer to the substrate crystal, and
a second ternary compound semiconductor layer that has a higher content of a binary compound semiconductor whose lattice constant is closest to the lattice constant of said semiconductor thin-film crystal, among said binary compound semiconductors, wherein said second ternary compound is placed at a position closer to the semiconductor thin-film crystals.

10. The semiconductor device according to claim 9, wherein
said substrate is GaAs;
said thin-film crystals are lattice-matched to InP; and
said buffer layer has either a set of InGaAs system materials and InGaP system materials or a set of InAlAs system materials and InGaP system materials, wherein the InGaAs system material layer that has a higher Ga content or the InAlAs system material layer that has a higher Al content is the first ternary compound, and the InGaP system material layer that has a higher In content is the second ternary compound.

11. An electronic device, wherein said electronic device includes a semiconductor device comprising:
a substrate crystal plane;
a buffer layer; and
thin-film crystals deposited on said substrate crystal with said buffer layer interposed therebetween, wherein each of said thin-film crystals has a lattice constant in a direction parallel to said substrate crystal plane that is different from a lattice constant of said substrate crystal,
further wherein said buffer layer comprises
first alloy compound semiconductor layers with thermal resistivities that increase with increasing lattice constant when the lattice constant thereof is changed between the lattice constant of said substrate crystal and the lattice constant of said semiconductor thin-film crystal by changing the composition of said first alloy compound
and second alloy compound semiconductor layers with thermal resistivities that decrease with increasing lattice constant when the lattice constant thereof is changed between the lattice constant of said substrate crystal and the lattice constant of said semiconductor thin-film crystal by changing the composition of said second alloy compound.

12. An electronic device according to claim 11, wherein
at least said first alloy compound semiconductor layer is formed using a plurality of alloy compound semiconductor thin-film layers, each with thermal resistivities that increase with increasing lattice constant.

13. An electronic device according to claim 11, wherein
at least said second alloy compound semiconductor layer is formed using a plurality of alloy compound semiconductor thin-film layers, each with thermal resistivities that decrease with increasing lattice constant.

14. An electronic device according to claim 12, wherein
at least said second alloy compound semiconductor layer is formed using a plurality of alloy compound semiconductor thin-film layers, each with thermal resistivities that decrease with increasing lattice constant.

15. An electronic device according to claim 11, wherein
at least said first alloy compound semiconductor layer is an alloy compound semiconductor layer with a thermal resistivity that varies continuously within the first alloy compound semiconductor layer.

16. An electronic device according to claim 14, wherein
at least said second alloy compound semiconductor layer is an alloy compound semiconductor thin-film layer with a thermal resistivity that varies continuously within the second alloy compound semiconductor layer.

17. A semiconductor device according to claim 15, wherein
at least said second alloy compound semiconductor layer is an alloy compound semiconductor thin-film layer with a thermal resistivity that varies continuously within the second alloy compound semiconductor layer.

18. A semiconductor device according to claim 11, wherein
said substrate crystal is GaAs,
the lattice constant of said semiconductor thin-film crystals are matched to that of InP,
said first alloy compound semiconductor layer is either an InGaAs system material or an InAlAs system material, and
said second alloy compound semiconductor layer is an InGaP system material.

19. The electronic device of claim 11, wherein said electronic device is a portable telephone.

20. The electronic device of claim 18, wherein said electronic device is a portable telephone.
